(19) United States
(12) Patent Application Publication
(10) Pub. No.: US 2014/0290718 A1
(43) Pub. Date: Oct. 2, 2014

(54) SUPPORT FOR SOLAR ENERGY CAPTURE DEVICE

(71) Applicant: Nicholas Jackson, JR., Davisburg, MI (US)

(72) Inventor: Nicholas Jackson, JR., Davisburg, MI (US)

(73) Assignee: A. RAYMOND ET CI, Grenoble (FR)

(21) Appl. No.: 14/232,441

(22) PCT Filed: Jul. 13, 2012
(86) PCT No.: PCT/US12/46698

§ 371 Date: Jun. 23, 2014

Related U.S. Application Data
(60) Provisional application No. 61/507,197, filed on Jul. 13, 2011.

(51) Int. Cl. H01L 31/042

(52) U.S. Cl. CPC H01L 31/0422
USPC 136/251

(57) ABSTRACT

A support for a solar energy capture device is shown and described. The support for the solar capture device may include at least one base positionable on a structure, at least one rail secured with the base, the rail capable of operatively holding a solar energy capture device. The support for the solar capture device may also include at least one weight member held within with the base, the weight member capable of holding the base on the structure free from fastening the base to the structure.

### CROSS-REFERENCE TO RELATED APPLICATION

This application claims the benefit of U.S. Provisional Patent Application No. 61/507,197, entitled “Solar Tube Support Rail,” filed on Jul. 13, 2011, which is hereby incorporated in its entirety by reference.

### FIELD OF INVENTION

The present invention generally relates to a support for solar energy capture devices, and more particularly for a support apparatus for supporting a solar energy capture device.

### BACKGROUND

Solar technology seeks to convert energy from the sun into electricity and reduce demands on conventional sources of electricity, such as fossil fuels. Solar cells convert sunlight into direct current. Typically, multiple solar cells are grouped together and mounted on a roof or other similar structure to receive exposure to direct sunlight.

Solar cells include traditional flat solar panels as well as alternative cells, such as solar tubes. Solar tubes, like solar panels, are designed to collect solar energy from the sun, but have a cylindrical or tubular shape to direct sunlight into the tube. Still further, solar cells may take any appropriate shape and be of any appropriate size.

Solar capture devices require special fixturing to support such, especially in light of the electrical energy produced by such. For example, solar tubes require unique mounting arrangements, much different than traditional solar panels. Mounting devices, such as solar tube rails, have been designed to facilitate both electrical connections between individual solar tubes and connection of the solar tubes to a roof or other similar structure.

Commonly, mounting rails may be formed out of metal, such as stainless steel, to provide an electrical connection between individual solar tubes. For example, the rail may comprise a plurality of openings in the metal rail to receive solar tubes therein. The openings may be connected electrically by the metal rail. The metal rail may be covered by an insulating substance, such as a molded layer of santoprene.

Still further, solar panels and other shaped solar capture devices may utilize support members that may include some kind of rail. These rails similarly are formed out of metals, such as stainless steel or aluminum.

While these designs allow for both electrical interconnection of the solar tubes or other solar capture device and structural connection to a roof or other structure, there are drawbacks. For example, the metal or stainless steel rail is heavy and expensive to manufacture. Further, the metal rail design lacks desired durability performance over the life of the product, especially given their generally continuous exposure to the environment. Still further, these metal rails are often conductive of electricity, which may require additional insulative materials to be used, may make them dangerous and may further make them somewhat dangerous to contact.

Therefore, an improved solar capture device support and rail are needed. There is a need for a rail that does not include the drawbacks of the metal rails. There is a need for a rail that is generally non-conductive, able to withstand all kinds of weather conditions, has a long life despite being exposed to the elements, and is easy to handle.

### BRIEF DESCRIPTION OF THE DRAWINGS

The operation of the invention may be better understood by reference to the detailed description taken in connection with the following illustrations, wherein:

FIG. 1 is a front perspective view of embodiments of a support for a solar capture device;

FIG. 2 is a rear perspective view of embodiments of the support for a solar capture device;

FIG. 3 is a rear perspective view of embodiments of the support for a solar capture device;

FIG. 4 is a front perspective view of other embodiments of a support for a solar capture device;

FIG. 5 is a perspective view of embodiments of a conductive strip for the support for the solar capture device of FIGS. 2 and 4;

FIG. 6 is a side perspective view of embodiments of a support for a solar capture device; and

FIG. 7 is a perspective view of a seal cup for the support for a solar capture device of FIGS. 1, 4 and 6.

FIG. 8 is a perspective view of embodiments of a support for a solar capture device.

FIG. 9 is a perspective view of embodiments of a support for a solar capture device.

FIG. 10 is a perspective view of embodiments of a support for a solar capture device.

FIG. 11 is a cross-sectional view of embodiments of a rail member for the support for a solar capture device of FIG. 10.

### SUMMARY

A support for a solar energy capture device is shown and described. The support for the solar capture device may include at least one base positionable on a structure, at least one rail secured with the base, the rail capable of operatively holding a solar energy capture device. The support for the solar capture device may also include at least one weight member held within with the base, the weight member capable of holding the base on the structure free from fastening the base to the structure.

A support for a solar energy capture device may include a rail capable of attaching to a structure, where the rail is formed from non-conductive composite material. The support may also include a solar capture device holding member secured to the rail, the solar device holding member capable of operatively positioning the solar capture device.

A support for a solar energy capture device may include a non-conductive composite rail capable of attaching to a structure, where the rail comprises polyurethane and a plurality of glass fibers, and a conductive strip attached to the non-conductive composite rail. The support may also include a solar capture device holding member in operative communication with the conductive strip, the solar device holding member capable of operatively positioning the solar capture device.

A solar capture device may include a panel member capable of capturing solar energy. The solar capture device may also include a rail secured with the panel member, the rail being formed from non-conductive composite material.

### DETAILED DESCRIPTION

Reference will now be made in detail to exemplary embodiments of the present invention, examples of which are illustrated in the accompanying drawings. It is to be understood that other embodiments may be utilized and structural and functional changes may be made without departing from the respective scope of the invention. Moreover, features of the various embodiments may be combined or altered without departing from the scope of the invention. As such, the following description is presented by way of illustration only and should not limit in any way the various alternatives and modifications that may be made to the illustrated embodiments and still be within the spirit and scope of the invention.

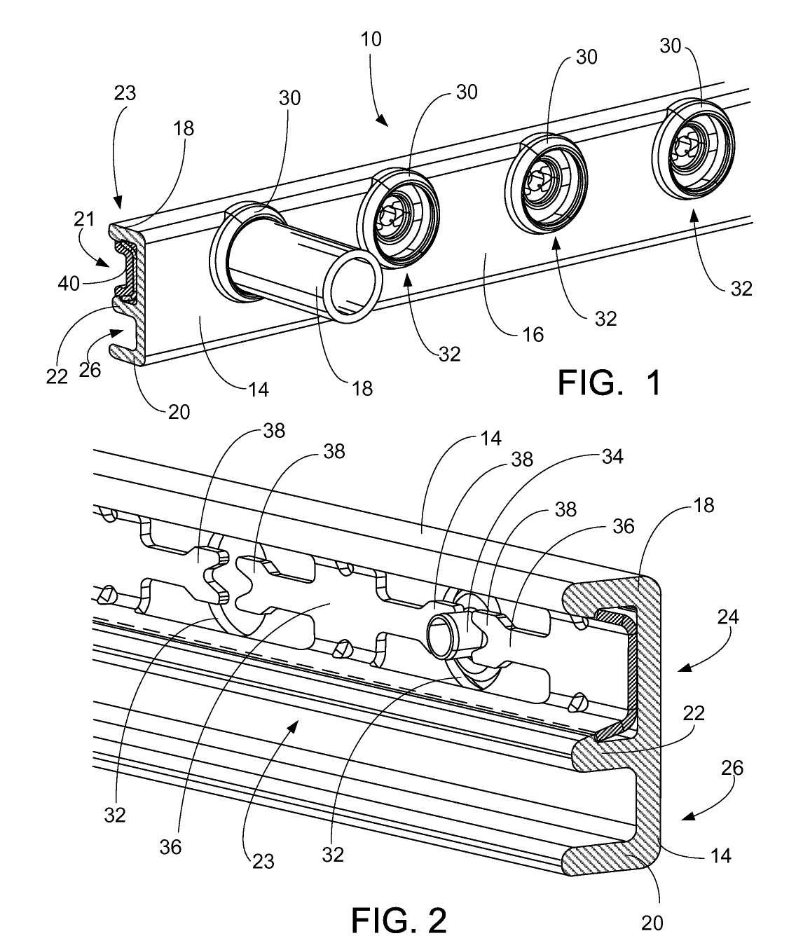

A support for a solar capture device 10 is generally provided, as illustrated in FIGS. 1-5. The support 10 may be designed to interconnect a solar capture device such as a solar tube 12 as shown in FIG. 1 to any appropriate structure, such as a roof, building structure or the like. The support 10 may eliminate or significantly reduce the use of expensive, heavy materials and instead utilize lighter, more cost efficient materials as described in more detail below.

The support 10 may include a rail member 14. The rail member 14 may be capable of connection to an appropriate building structure, such as a roof or other applicable structure in any appropriate manner. The rail member 14 may be any appropriate size, such as by way of a non-limiting example 8-10 feet long. The rail member 14 may also be of any appropriate shape, such as generally rectangular, ovoid, ovally, or the like. The rail member 14 may include a front face 16. The front face 16 may extend along a length of the rail member 14 and may be generally flat or planar. The front face 16, however, may be of any appropriate shape and is not limited to being generally flat—e.g., the front face 16 may be sinusoidal, curved, ribbed, ridged, or the like.

The rail member 14 may be formed from any appropriate non-conductive composite material. The rail member 14 may be generally free from any conductive material, i.e., it is made of non-electrically conductive material such that it may not be capable of transferring electricity. Instead, the rail member 14 may act like an insulator. Further still, the rail member 14 may be generally non-metallic, i.e., it may be generally free of metals such as aluminum any other such metals.

The non-conductive composite rail member 14 may be made through any appropriate method, including, without limitation an opening molding process, such as hand lay-up, spray-up, filament winding, or any closed molding, such as compression molding, pultrusion, reinforced reaction injection molding, resin transfer molding, vacuum bag molding, vacuum infusion processing, centrifugal casting, continuous lamination or the like. By way of a non-limiting example, the rail member 14 may be pultruded. Pultrusion is a continuous process of manufacturing of composite materials with generally constant cross-sectional shape whereby reinforced fibers may be pulled through a resin and into a heated die. While in the heated die, the resin may undergo polymerization, which may harden the rail member 14 to the appropriate stiffness.

The non-conductive composite rail members 14 may be 20-25% of the weight of steel and 70% of the weight of aluminum rail members and further may be free of any conductive material. The non-conductive composite rail member 14 may be easily transported, handled and lifted into place. The rail member 14 may be preassembled and shipped to the job site ready for installation.

Still further, the rail member 14 being formed from a non-conductive composite material may generally prevent if from rotting or otherwise deteriorating and may further be generally impervious to a broad range of corrosive elements. The non-conductive composite rail member 14 may be transparent to radio waves, microwaves, and other electromagnetic frequencies, which may result in it generally being free from interfering with electronic and wireless products, e.g., telephones, wireless routers and the like. Still further, the coefficient of thermal expansion of the non-conductive composite rail member 14 may slightly less than steel and significantly less than aluminum. This may be of particular benefit when the rail member 14 supports any kind of solar capture device.

Another important feature of the non-conductive composite rail member 14 is that it may be drilled, sawed, ground or the like within minutes after emerging from the applicable die. This may provide a reduced time by which the rail member 14 may be created and formed, which may reduce the costs and/or may allow for increased production thereof.

In accordance with one aspect of the present teachings, the rail member 14 may have a low thermal conductivity and may be electrically non-conductive. The rail member 14 may be formed of a non-conductive material to circumvent the need for any additional insulation layer, which may be required with some of the prior art version. In some embodiments, the rail member 14 may be formed from a glass fiber reinforced pultrusion. The rail member 14 being made from glass fiber reinforced pultrusion may result in it exhibiting excellent mechanical properties at extreme temperatures, whereby other such product are not capable of operating appropriately. The glass fiber reinforced non-conductive composite rail member 14 may be able to exhibit positive mechanical properties even at negative 70° F. and 200° F. In fact, the tensile strength and impact strength of glass fiber reinforced rail member 14 may be greater at negative 70° F. than at 80° F. By way of a non-limiting example, the rail member 14 may be made from a glass reinforced pultrusion such as a polyurethane, such as Baydur PUL 2500. It should be understood, however, that the rail member 14 may be formed from various methods using non-conductive composite materials without departing from the present teachings. The present teachings are not limited to be pultruded.

Still further, the non-conductive composite rail member 14 may be pigmented throughout the thickness thereof and may be made to virtually any desired custom color (including an off white). Special surfacing veils may also be used with the rail member 14 so as to create special surface appearances as wood grain, marble, granite, etc. Any appropriate surface appearance may be used without departing from the present teachings. The special surfacing veil may allow the rail member 14 to generally match the surface finish of the support structure to which it may be secured. This may, therefore, allow the rail member 14 to be virtually invisible as it may be camouflaged.

In embodiments, illustrated in FIGS. 1-3, the rail member 14 may include a front face 16 and a top flange 18 and bottom flange 20. The top and bottom flanges 18, 20 may extend in generally the same direction from the front face 16 to form a substantially U-shaped member. The rail member 14 may further include a center flange 22, which may be located on a side of the rail member 14 opposite the front face 16. The center flange 22 may divide a back side 23 of the rail member 14 between a first or upper channel 24 and a second or lower channel 26. The first and second channels 24, 26 may be any appropriate size and shape, such as equally sized or uniquely sized. While the first and second channels 24, 26 may be shown as being upper and lower, the present teachings are not limited to such. The first and second channels 24, 26 may be appropriately positioned relative to one another in any appropriate direction.

The support 10 may include one or more cups 30 disposed along a length of the front face 16 of the rail member 14. The cups 30 may be aligned with the first channel 24, the second channel 26, or both the first and second channels 24, 26 as appropriate. The cups 30 may be any appropriate shape, such as generally round, cylindrical, rectangular, or the like, and may be configured to receive and support a solar capture device, such as the solar tube 12 therein—an exemplary embodiment of which is shown in FIG. 7. The cups 30 may be made of any appropriate material. By way of a non-limiting example, the cups 30 may be composed of an insulating material such as santoprene, or any other insulating material known and used in the art or any other appropriate material.

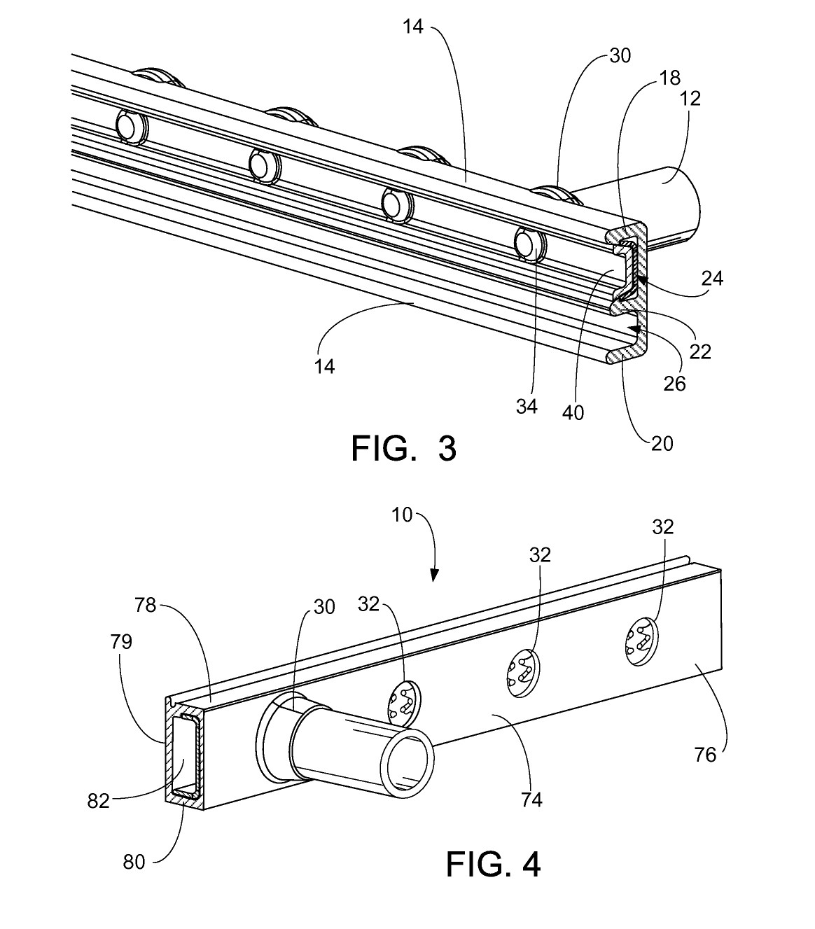

The rail member 14 may include a plurality of holes 32 disposed along a length of the front face 16. The holes 32 may be arranged to align with a portion of the cups 30, such as centrally aligned with each cup 30. The holes 32 may be sized and shaped to receive a portion of the solar capture device, such as the solar tube 12, such as a conductive portion 34 of the solar tube 12, therein. The conductive portion 34 may extend through the hole 32 in the front face 16 and protrude through a back portion 23 of the support rail 10. By way of a non-limiting example, as illustrated in FIG. 3, the conductive portion 34 may extend into the upper channel 24.

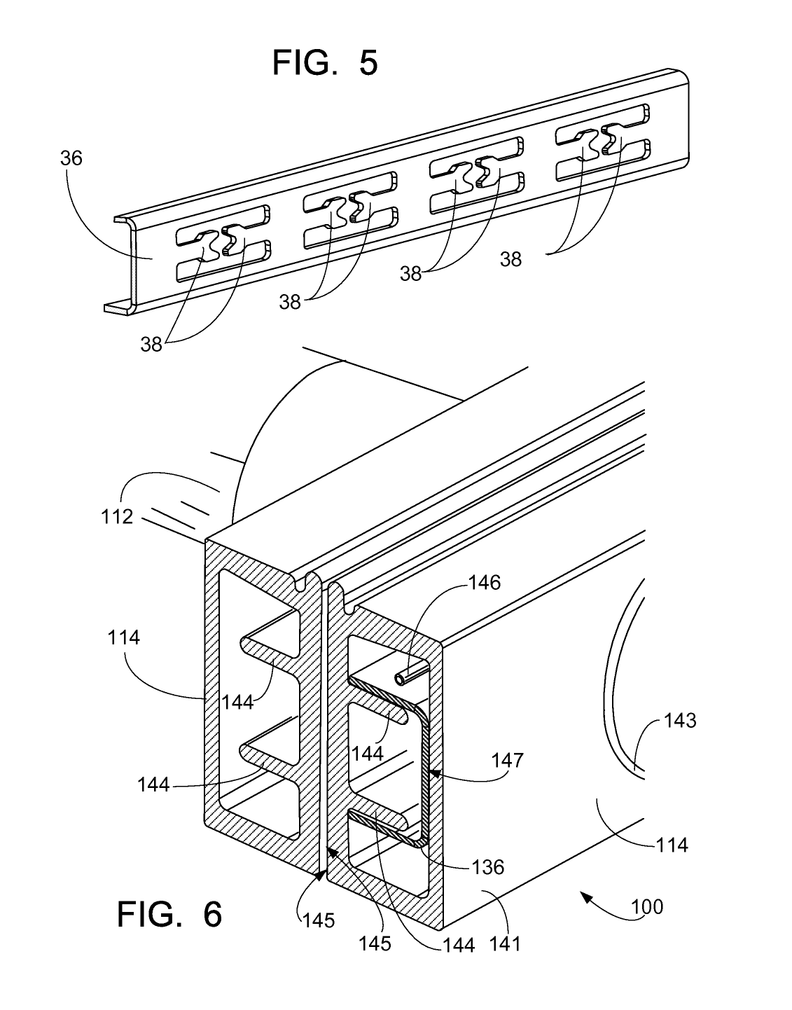

The support 10 may include at least one conductive strip 36, an exemplary embodiment of which is shown in FIG. 5. The support 10 may include any appropriate number of conductive strips 36 and the present teachings are not limited to a particular number of conductive strips 36. The conductive strip 36 may electrically join a plurality of the solar tubes 12 inserted into the cups 30 and conduct the captured energy to a desired location. The conductive strip 36 may be any appropriate size and shape, such as configured to fit within the upper or lower channel 24, 26 or both the upper and lower channels 24, 26. The conductive strip 36 may be positioned within the channel that may be aligned with the cups 30, as shown in FIGS. 1-3. By way of a non-limiting example, the conductive strip 36 may be positioned adjacent the back side 23 of the rail member 14. The conductive strip 36 may comprise prongs 38 that may be positioned about each hole 32. The prongs 38 may engage the conductive portion 34 of the solar tube 12, an example of which is shown in FIG. 2.

The support 10 may include an insulation layer 40. The insulation layer 40 may be configured to insulate the conductive strip 36 from the external environment, such as for example, protecting the conductive strip 36 from contact by a person, animal or the like. The insulation layer 40 may be any appropriate size and shape, such as sized and shaped to fit within the first or second channel 24, 26, or both the first and second channels 24, 26. As illustrated in FIGS. 1 and 3, the insulation layer 40 may be positioned adjacent the conductive strip 36 such that the conductive strip 36 is between the rail member 14 and the insulation layer 40. The insulation layer 40 may be composed of any appropriate material, such as santoprene or any other insulation material known or used in the art. The insulation layer 40 may be molded or otherwise formed using any processes known in the art.

The support 10 may be assembled using any methods known in the art. For example, the non-conductive composite rail member 14 may be formed using any appropriate method, including, without limitation, an opening molding process, such as hand lay-up, spray-up, filament winding, or any closed molding, such as compression molding, pultrusion, reinforced reaction injection molding, resin transfer molding, vacuum bag molding, vacuum infusion processing, centrifugal casting, continuous lamination or the like as described in more detail above. It is found in practice that pultrusion is an exemplary method of forming the non-conductive composite rail member 14. Holes 32 may be integrally formed in the front face 16 of the rail member 14 or may be punched or otherwise formed into the rail member 14. A conductive strip 36 may be inserted into the upper channel 24 or lower channel 26 and aligned with holes 32. Cups 30 may be mounted on the rail member 14 and arranged about the holes 32. The cups 30 may be mounted using an adhesive or other parts or hardware as is known in the art. One or more solar tubes 12 may be inserted into the cups 30 and configured such that the conductive portion 34 may extend through the front face 16 and engage prongs 38 on the conductive strip 36. An insulation layer 40 may be positioned adjacent to the conductive strip 36. It will be appreciated that the steps for making and assembling the support rail 10 may be performed in any appropriate order.

In some embodiments, the support 10 may include a rail member 74 that may be of a generally tubular shape with a generally rectangular cross-sectional shape as shown in FIG. 4. The rail member 74 may be capable of connection to an appropriate building structure, such as a roof or other applicable structure in any appropriate manner. The rail member 74 may be any appropriate size, such as by way of a non-limiting example 8-10 feet long. The rail member 74 may be of similar construction to that of rail member 14. The rail member 74 may include a front face 76. The front face 76 may be of any appropriate shape and is not limited to being generally flat—e.g., the front face 76 may be sinusoidal, curved, ribbed, ridged, or the like.

The rail member 74 may be made from any appropriate non-conductive composite material resulting in a rail member 74 that may have a low thermal conductivity and may be electrically non-conductive. The rail member 74 may be formed through any appropriate method, including, without limitation, an opening molding process, such as hand lay-up, spray-up, filament winding, or any closed molding, such as compression molding, pultrusion, reinforced reaction injection molding, resin transfer molding, vacuum bag molding, vacuum infusion processing, centrifugal casting, continuous lamination or the like as described in more detail above. The rail member 74 may be generally free from any conductive material, i.e., it is made of non-electrically conductive material such that it may not be capable of transferring electricity. Instead, the rail member 74 may act like an insulator. Further still, the rail member 74 may be generally non-metallic, i.e., it may be generally free of metals such as aluminum any other such metals.

It is found in practice that pultrusion is an exemplary method of forming the non-conductive composite rail member 74. The non-conductive composite rail members 74 may be 20-25% of the weight of steel and 70% of the weight of aluminum rail members and further may be free of any conductive material. The non-conductive composite rail member 74 may be easily transported, handled and lifted into place. The rail member 74 may be preassembled and shipped to the job site ready for installation.

Still further, the rail member 74 being formed from a non-electrically conductive material may generally prevent it from rotting or otherwise deteriorating and may further be generally impervious to a broad range of corrosive elements. The non-conductive composite rail member 74 may be transparent to radio waves, microwaves, and other electromagnetic frequencies, which may result in it generally being free from interfering with electronic and wireless products, e.g., telephones, wireless routers and the like. Still further, the coefficient of thermal expansion of the non-conductive composite rail member 74 may slightly less than steel and significantly less than aluminum. This may be of particular benefit when the rail member 74 supports any kind of solar capture device.

In accordance with one aspect of the present teachings, the rail member 74 may be formed of a non-conductive material to circumvent the need for any additional insulation layer, which may be required with some of the prior art version. In some embodiments, the rail member 74 may be formed from a glass fiber reinforced pultrusion. The rail member 74 being made from glass fiber reinforced pultrusion may result in it exhibiting excellent mechanical properties at extreme temperatures, whereby other such product are not capable of operating appropriately. The glass fiber reinforced non-conductive composite rail member 74 may be able to exhibit positive mechanical properties even at negative 70° F. and 200° F. By way of a non-limiting example, the rail member 74 may be made from a glass reinforced pultrusion such as a polyurethane, such as Baydur PUL 2500.

Still further, the non-conductive composite rail member 74 may be pigmented throughout the thickness thereof and may be made to virtually any desired custom color (including an off white). Special surfacing veils may also be used with the rail member 74 so as to create special surface appearances as wood grain, marble, granite, etc. Any appropriate surface appearance may be used without departing from the present teachings. The special surfacing veil may allow the rail member 74 to generally match the surface finish of the support structure to which it may be secured. This may, therefore, allow the rail member 74 to be virtually invisible as it may be camouflaged.

In embodiments, illustrated in FIG. 4, the rail member 74 may include the front face 76 and a top wall 78, a rear wall 79 and bottom wall 80, which may form a channel 82 therebetween. The support 10 may include one or more cups 30 disposed along a length of the front face 76 as previously described. The cups 30 may be configured to receive and support a solar capture device, such as the solar tube 12 therein. The rail member 74 may include a plurality of holes 32 disposed along a length of the front face 76. The holes 32 may be arranged to align with a portion of the cups 30, such as centrally aligned with each cup 30. The holes 32 may be sized and shaped to receive a portion of the solar capture device, such as the solar tube 12, such as the conductive portion 34 of the solar tube 12, therein. The conductive portion 34 may extend through the hole 32 in the front face 76 and protrude into the channel 82.

The support 10 may include at least one conductive strip 36. The support 10 may include any appropriate number of conductive strips 36 and the present teachings are not limited to a particular number of conductive strips 36. The conductive strip 36 may electrically join a plurality of the solar tubes 12 inserted into the cups 30 and conduct the captured energy to a desired location. The conductive strip 36 may be any appropriate size and shape, such as configured to fit within the channel 82.

The rail member 74 having a generally closed body may eliminate need for the insulation layer 40 as described above. The rear wall 79 may generally prevent a person from accessing the conductive strip 36, which may make the insulation layer unnecessary. It should be understood, however, that the insulation layer 40, however, may be included without department from the present teachings.

Additional embodiments of a support for a solar capture device according the present teachings are described below. In the descriptions, all of the details and components may not be fully described or shown. Rather, the main features or components are described and, in some instances, differences with the above-described embodiment may be pointed out. Moreover, it should be appreciated that these additional embodiments may include elements or components utilized in the above-described embodiment although not shown or described. Thus, the descriptions of these additional embodiments are merely exemplary and not all-inclusive nor exclusive. Moreover, it should be appreciated that the features, components, elements and functionalities of the various embodiments may be combined or altered to achieve a support for a solar capture device without departing from the spirit and scope of the present invention.

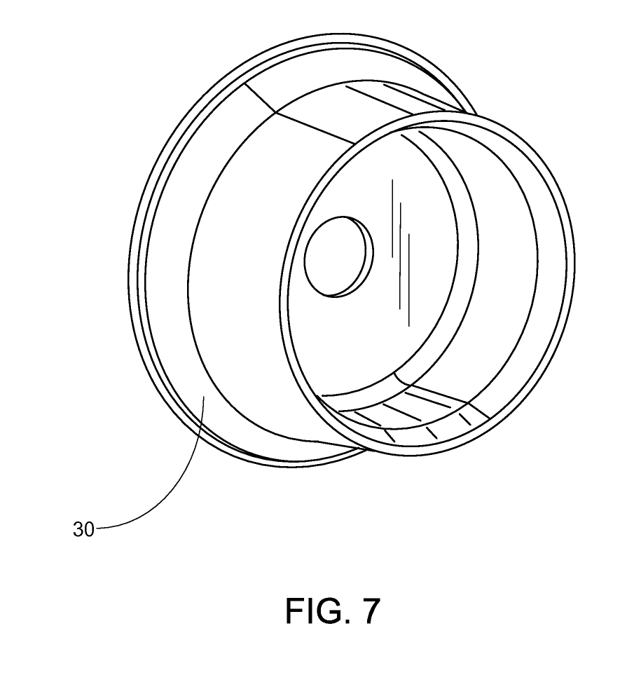

In embodiments, illustrated in FIG. 6, a support for a solar capture device 100 may include a rail member 114. The rail member 114 may be any appropriate size, such as 8-10 feet in length, and be of any appropriate shape, such as having a generally rectangular, ovoid, circular or the like cross section. The rail member 114 may include a front face 141. The font face 141 may be any appropriate shape, such as for example comprising a generally flat surface. The rail member 114 may have a generally closed shape. The closed arrangement of the rail member 114 may protect and seal internal components from the outer environment. The rail member 114 may include a generally flat back surface 145 to allow a plurality of rail members 114 to be arranged in a back-to-back configuration, as illustrated in FIG. 6.

The rail member 114 may be formed from any appropriate process, including, without limitation, an opening molding process, such as hand lay-up, spray-up, filament winding, or any closed molding, such as compression molding, pultrusion, reinforced reaction injection molding, resin transfer molding, vacuum bag molding, vacuum infusion processing, centrifugal casting, continuous lamination or the like as described in more detail above. By way of a non-limiting example, the rail member 114 may be formed through any appropriate pultrusion method. The rail member 114 may be generally free from any conductive material, i.e., it is made of non-electrically conductive material such that it may not be capable of transferring electricity. Instead, the rail member 114 may act like an insulator. Further still, the rail member 114 may be generally non-metallic, i.e., it may be generally free of metals such as aluminum any other such metals.

The non-conductive composite rail member 114 may be 20-25% of the weight of steel and 70% of the weight of aluminum rail members. The non-conductive composite rail member 114 may be easily transported, handled and lifted into place. The rail member 114 may be preassembled and shipped to the job site ready for installation.

Still further, the rail member 114 being formed from a non-electrically conductive composite material may generally prevent if from rotting or otherwise deteriorating and may further be generally impervious to a broad range of corrosive elements. The non-conductive composite rail member 114 may be transparent to radio waves, microwaves, and other electromagnetic frequencies, which may result in it generally being free from interfering with electronic and wireless products, e.g., telephones, wireless routers and the like. Still further, the coefficient of thermal expansion of the non-conductive composite rail member 114 may slightly less than steel and significantly less than aluminum. This may be of particular benefit when the rail member 114 supports any kind of solar capture device.

In accordance with one aspect of the present teachings, the rail member 114 may have a low thermal conductivity and may be electrically non-conductive. The rail member 114 may be formed of a non-conductive material to circumvent the need for any additional insulation layer, which may be required with some of the prior art version. In some embodiments, the rail member 114 may be formed from a glass fiber reinforced pultrusion. The rail member 114 being made from glass fiber reinforced pultrusion may result in it exhibiting excellent mechanical properties at extreme temperatures, whereby other such product are not capable of operating appropriately. The glass fiber reinforced non-conductive composite rail member 114 may be able to exhibit positive mechanical properties even at negative 70° F. and 200° F. By way of a non-limiting example, the rail member 114 may be made from a glass reinforced pultrusion such as a polyurethane, such as Baydur PUL 2500.

The rail member 114 may include one or more support ledges 144. The support ledges may be disposed internal to the rail member 114. By way of a non-limiting example, as illustrated in FIG. 6, the rail member 114 may include two support ledges 144 extending from a back wall 145 of the rail member 114. The support ledges 144 may extend along a length of the rail member 114 and may be spaced apart from and arranged parallel to one another. The support ledges 144 may be configured to position and support internal components of the support 100.

The rail member 114 may include a plurality of holes 143 disposed along a length of the front face 141. As previously described, the holes 143 may be sized and shaped to receive a portion of a solar capture device, such as the solar tube 112. Specifically, the holes 143 may be sized and shaped to receive a conductive portion of the solar tube 112, therein. The conductive portion may extend through the hole 143 in the front face 141 and may protrude into the closed portion of the rail member 114. One or more the cups 30 may be disposed along the length of the front face 141 and arranged to align with the holes 143. The cups 30 may be made of any appropriate material, such as santoprene. The cups 30 may be configured to receive the solar tube 112 therein and may provide a seal between the solar tube 112 and the outer environment.

The rail member 114 may include a conductive strip 136 electrically joining a plurality of solar tubes 114. The conductive strip 136 may be any appropriate size and shape, such as configured to fit within the interior of the rail member 114. By way of a non-limiting example, as illustrated in FIG. 6, the conductive strip 136 may be sized and shaped to engage an interior perimeter of the rail member 114. Alternatively, the conductive strip 136 may be sized and shaped to engage the support ledges 144. In either configuration, the conductive strip 136 may be positioned directly adjacent to an interior surface 147 of the rail member 114. The conductive strip 136 may include prongs that are positioned about each hole 132. The prongs may engage the conductive portion of the solar tube 112 as previously described. The conductive strip 136 may further include a wire 146, such as a copper wire, connected to the conductive strip 136. The wire 146 may help increase the flow of energy/electricity from the solar tubes 112 through the support 100.

The rail member 114 may be formed using any appropriate method as set forth above, including, without limitation through pultrusion as described in more detail above. Holes 143 may be integrally formed in the front face 141 of the rail member 114 or may be punched or otherwise formed into the rail member 114. A conductive strip 136 may be inserted into the rail member 114 and may be aligned with holes 143. Cups 30 may be mounted on the front face 141 and arranged about the holes 143. The cups 30 may be mounted using an adhesive or other parts or hardware as is known in the art. One or more solar tubes 112 may be inserted into the cups 30 and configured such that the conductive portion may extend through the front face 141 and may engage prongs on the conductive strip 136. It will be appreciated that the steps for making and assembling the support 100 may be performed in any appropriate order.

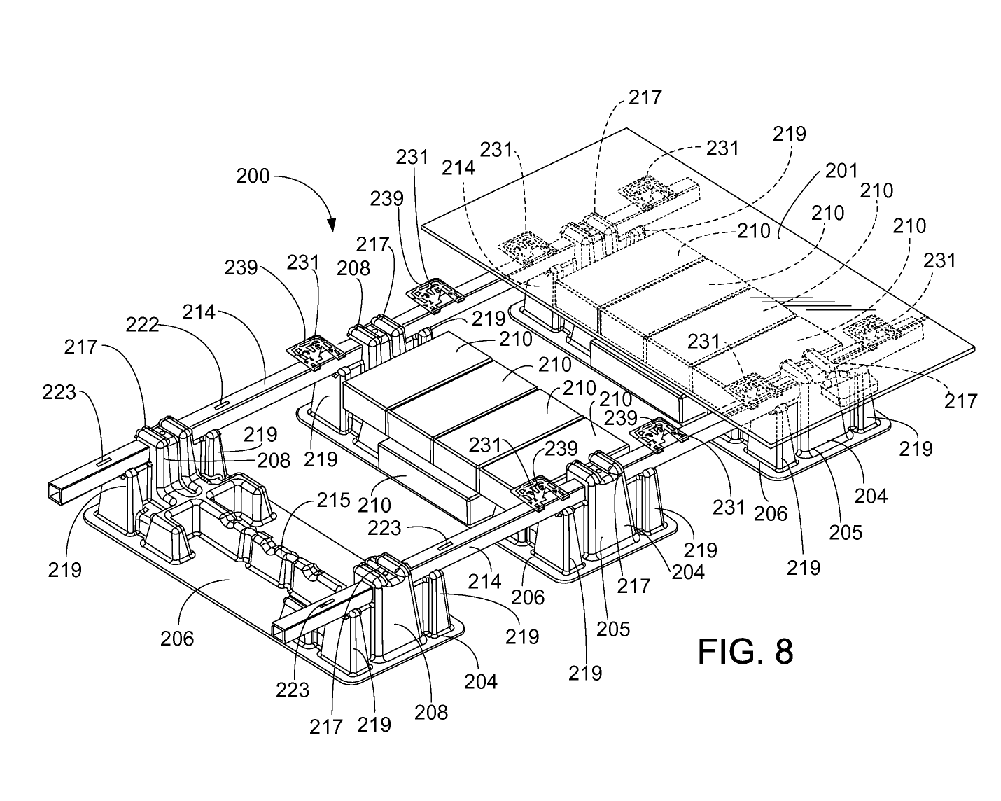

In embodiments illustrated in FIG. 8, a support 200 for a solar capture device 201, such as by way of a non-limiting example, solar panels 201, is shown. The support 200 may include a base member 204. The base member 204 may be capable of being placed or otherwise positioned on a structure, such as by way of a non-limiting example, a roof of a building. The base member 204 may be of any appropriate shape and size. By way of a non-limiting example, the base member 204 may be generally rectangular, square, ovoid, ovally, circular, or any combination of such shapes. The base member 204 may be made of any appropriate material, including, without limitation, plastics, rubber or a combination of such. The base member 204 may be made of a non-electrically conductive material. In some embodiments, the base member 204 may be a vacuum formed, but is not limited to such. The base member 204 may be formed such as through, an opening molding process, such as hand lay-up, spray-up, filament winding, or any closed molding, such as compression molding, pultrusion, reinforced reaction injection molding, resin transfer molding, vacuum bag molding, vacuum infusion processing, centrifugal casting, continuous lamination or the like.

The base member 204 may include a generally planar portion 206 and a retaining member 208, as described in more detail below. The support 200 may include at least one ballast 210. The ballast 210 may generally provide weight to the base member 204 to generally keep the base member 204 in contact with the structure on which it is positioned. The ballast 210 may be of any appropriate material, such as by way of a non-limiting example, metal, plastic, rubber or the like. In some embodiments, the ballast 210 may be a plastic body with material such as sand inserted and held therein. The support 200 may include a plurality of ballast 210. The appropriate number of ballasts 210 to be used with the support 200 may depend on several factors, such as by way of a non-limiting example, the length of the rail, the size of the solar panels, the environment the support 200 may be used, the location of the support 200, the structure on which the support 200 is placed. The greater the weight required to keep the support 200 in contact with the appropriate structure on which it is placed, the more ballasts 210 may be used. While a generally rectangular ballast 210 is shown and described, any kind of weight may be used. The present teachings are not limited to the ballast shown. By way of a non-limiting example, bricks, concrete blocks, or any such heavy item may be used to provide the weight to generally keep the support 200 in contact with the support on which it is placed.

The ballasts 210 may be of a shape and size such that they are capable of being stacked onto the generally planar portion 206 of the base 204. In some embodiments, the dimensions of the generally planar portion 206 may be such that a predetermined number of ballasts 210 may be capable of tightly fitting within the appropriate planar portion 206. Still further, the shapes and sizes of the ballasts 210 and the generally planar portion 206 may be such that the ballasts 210 may be arranged on the generally planar portion 206 to maximize the number of ballasts 210 that may fit thereon. By way of a non-limiting example, the generally planar portion 206 of the base 204 may include six ballasts 210 positioned thereon. The generally planar portion 206 may include a vertically extending member 215 that may be of a shape and size to allow for a tight fit of the ballasts 210. The vertically extending member 215 may also in some embodiments, provide for additional rigidity for the generally planar portion 206 of the base 204.

The support 200 may also include at least one rail member 214. The rail member 214 may be of any appropriate shape and size and may be of any appropriate composite material. The rail member 214 may be formed through any appropriate method, including, without limitation, an opening molding process, such as hand lay-up, spray-up, filament winding, or any closed molding, such as compression molding, pultrusion, reinforced reaction injection molding, resin transfer molding, vacuum bag molding, vacuum infusion processing, centrifugal casting, continuous lamination or the like. By way of a non-limiting example, the rail member 214 may be formed through any appropriate pultrusion method. The rail member 214 may be generally free from any conductive material, i.e., it is made of non-electrically conductive material such that it may not be capable of transferring electricity. Instead, the rail member 214 may act like an insulator. Further still, the rail member 214 may be generally non-metallic, i.e., it may be generally free of metals such as aluminum any other such metals.

In some embodiments, the rail member 214 may be pultruded, i.e., put through a continuous process of manufacturing composite materials with generally constant cross-sectional shape whereby reinforced fibers may be pulled through a resin and into a heated die. While in the heated die, the resin may undergo polymerization, which may harden the rail member 214 to the appropriate stiffness. The non-conductive composite rail member 214 may be 20-25% of the weight of steel and 70% of the weight of aluminum rail members and further may be free of any conductive material. The non-conductive composite rail member 214 may be easily transported, handled and lifted into place. While the rail member 214 is described as being pultruded any appropriate method may be used without departing from the present teachings.

Still further, the rail member 214 being formed from non-conductive composite material may generally prevent if from rotting or otherwise deteriorating and may further be generally impervious to a broad range of corrosive elements. The non-conductive composite rail member 214 may be transparent to radio waves, microwaves, and other electromagnetic frequencies, which may result in it generally being free from interfering with electronic and wireless products, e.g., telephones, wireless routers and the like. Still further, the rail member 214 may have a low thermal conductivity, e.g., the coefficient of thermal expansion of the non-conductive composite rail member 214 may slightly less than steel and significantly less than aluminum. This may be of particular benefit when the rail member 214 supports any kind of solar capture device, such as the solar capture device 201 shown in FIG. 8. The rail member 214 may be formed of a non-conductive material to circumvent the need for any additional insulation layer, which may be required with some of the prior art versions.

In accordance with one aspect of the present teachings, the rail member 214 may be formed from a glass fiber reinforced pultrusion. The rail member 214 being made from glass fiber reinforced pultrusion may result in it exhibiting excellent mechanical properties at extreme temperatures, whereby other such product are not capable of operating appropriately. The glass fiber reinforced non-conductive composite rail member 214 may be able to exhibit positive mechanical properties even at negative 70° F. and 200° F. By way of a non-limiting example, the rail member 214 may be made from a glass reinforced pultrusion such as a polyurethane, such as Baydur PUL 2500.

The retaining members 208 of the base member 204 may include an engaging member 217 that may be capable of securing the rail member 214 in an operative position. In some embodiments, the retaining members 208 and the engaging members 217 may be integrally formed with the base member 204 as a monolithic member. In other embodiments, the retaining members 208 and the engaging members 217 may be attached with the base member 204 such as through subsequent processing. In such embodiments, the retaining members 208 and the engaging members 217 may be secured with the base member 204 in any appropriate manner. Still further, the engaging members 217 may be integrally formed with the retaining members 208 as a monolithic unit or may be attached through a subsequent operation. Alternatively, the engaging members 217 may be formed through a subsequent operation, such as by way of a non-limiting example, forming the engaging member 217 as an aperture, such as shown in FIG. 8. In such embodiments, the engaging members 217 may be capable of accepting through sliding engagement the rail member 214 generally holding the rail member 214 in an operative position. The engaging members 217, however, may operatively secure the rail member 214 in any appropriate manner. The present teachings are not limited to such.

The retaining members 208 may also include a pedestal portion 219. The pedestal portion 219 may be integrally formed with the retaining members 208 as a monolithic unit or may be attached or otherwise formed through a subsequent operation. Any appropriate number of pedestal portions 219 may be used without departing from the present teachings, such as by way of a non-limiting example, two pedestal portions 219 per retaining member 208, for a total of four pedestal portions 219 per base member 204. The pedestal portions 219 may be operatively positioned with the engaging members 217. By way of a non-limiting example, the pedestal portions 219 may be juxtaposed with the engaging members 217. In these embodiments, as the rail member 214 slidingly engages the engaging members 217, the rail member 214 may rest upon the pedestal portions 219. This may generally align the rail member 214 with the engaging members 217 and once the rail member 214 is appropriately engaged with the engaging member 217, the pedestal portion 219 may support the rail member 214. This support may generally prevent the rail member from bending and may generally keep the rail member 214 level, i.e., the pedestal portions 219 may act as a leveler for the rail member 214.

The rail member 214 may include at least one aperture 223, such as by way of a non-limiting example, the rail member 214 may include a plurality of apertures 223. The present teachings, however, are not limited to a specific number of apertures 223. The apertures 223 may be of any appropriate shape or size, such as generally rectangular, ovally, circular, ovoidal, square, or any combination of shapes. Further, the apertures 223 may be integrally formed with the rail member 214 as a monolithic unit, such as during the pultrusion thereof, or may be formed in a subsequent operation thereto.

The support 200 may include at least one bracket 231 that may be capable of selectively engaging the rail member 214. More specifically, the at least one bracket 231 may be selectively engaged with the aperture 223 of the rail member 214. In some embodiments, a portion of the brackets 231 may be capable of being inserted into the aperture 223 of the rail member 214. In the alternative, the rail member 214 may not include apertures. In such embodiments, the bracket 231 may attach directly to the rail 214 in any appropriate manner, such as welding, fastening, adhering, or the like.

The brackets 231 may be capable of holding in an appropriate position the applicable solar capture device 201. In some embodiments, the brackets 231 may include an elastomeric portion 237 on which the solar capture device 201 may sit. The combination of the weight of the solar capture device 201 and the friction occurring between contact of the solar capture device 201 and the elastomeric portion 237 of the bracket 231 may generally prevent the solar capture device from becoming disengaged. In some embodiments, the solar capture device 201 may be attached directly to the bracket 231 such as through the use of an appropriate fastener. In such embodiments, the fastener may be secured to the solar capture device 201 and into the bracket 231 in any appropriate manner. Still further, the solar capture device 201 may otherwise be operatively fixed with the bracket 231 in any appropriate manner. The present teachings are not limited to the specific manner in which the solar capture device 201 may be fixed with the bracket 231.

In some embodiments, the support 200 may include a plurality of base members 204, which may include a pair or rails 214 that may extend between each of the base members 204. More specifically and with reference to FIG. 8, the support 200 may include three base members 204 that may have a pair of rails 214 extending between the three base members 204. The base members 204 may be secured to the engaging members 217 of the base members 204. The rail members 214 may be slidingly engaged with the engaging members 217 as described above. The rail members 214 may include a plurality of apertures 223, such as the six shown. The apertures 223 may include brackets 231 selectively or fixedly attached thereto. Each base member 204 may have a solar capture device 201 positioned on the respective brackets 231 over the applicable base member 204.

In such embodiments, the appropriate wiring (not shown) from the solar capture device 201 to the appropriate electrical system (not shown) of the structure to which the electricity is being supplied is accomplished in any appropriate manner. The present teachings are not limited to any particular configuration. In some embodiments, the base members 204 and/or the ballasts 210 may include wire holding portions that may generally assist with positioning of the wires and may provide a generally more aesthetically pleasing appearance.

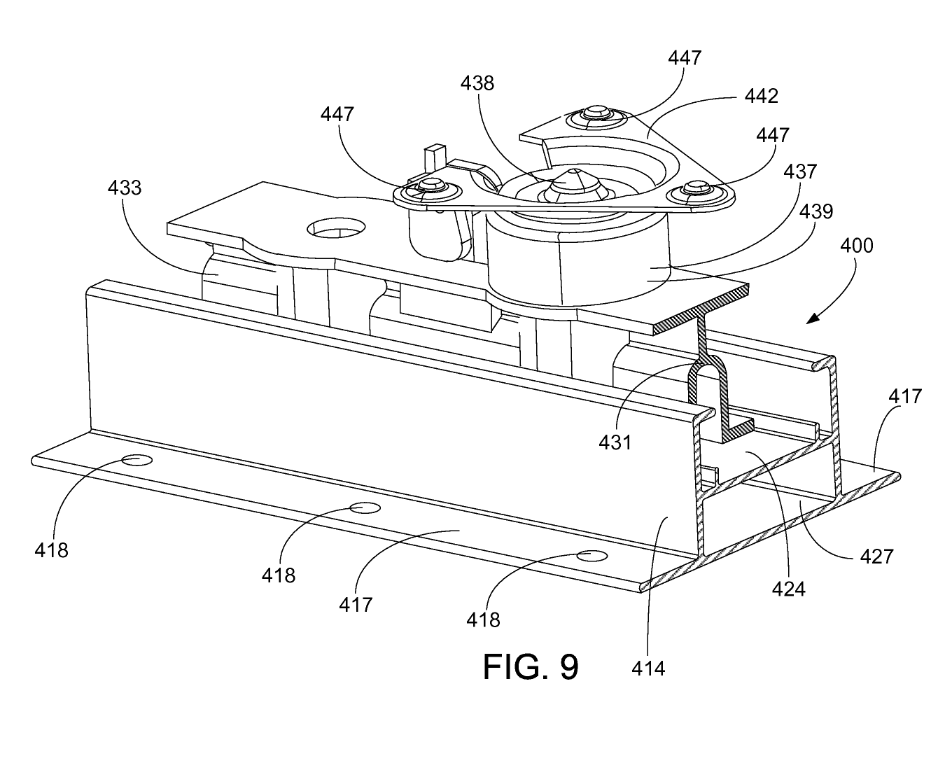

In embodiments shown in FIG. 9, a support 400 for a solar capture device (not shown) may be attached to a structure, such as a building or the like. In these embodiments, the support 400 may include a rail member 414 that may attach directly to the structure in any appropriate manner, such as through using fasteners, adhesives, or friction. The rail member 414 may be of any appropriate shape and size and may be of any appropriate non-conductive composite material. The rail member 414 may be formed through any appropriate method, including, without limitation through an opening molding process, such as hand lay-up, spray-up, filament winding, or any closed molding, such as compression molding, pultrusion, reinforced reaction injection molding, resin transfer molding, vacuum bag molding, vacuum infusion processing, centrifugal casting, continuous lamination or the like. The rail member 414 may be generally free from any conductive material, i.e., it is made of non-electrically conductive material such that it may not be capable of transferring electricity. Instead, the rail member 414 may act like an insulator. Further still, the rail member 414 may be generally non-metallic, i.e., it may be generally free of metals such as aluminum any other such metals.

In accordance with one aspect of the present teachings, the rail member 414 may be formed through pultrusion, i.e., put through a continuous process of manufacturing composite materials with generally constant cross-sectional shape whereby reinforced fibers may be pulled through a resin and into a heated die. While in the heated die, the resin may undergo polymerization, which may harden the rail member 414 to the appropriate stiffness. The non-conductive composite rail member 414 may be 20-25% of the weight of steel and 70% of the weight of aluminum rail members and further may be free of any conductive material. The non-conductive composite rail member 414 may be easily transported, handled and lifted into place.

Still further, the rail member 414 being formed from non-conduct composite material may generally prevent if from rotting or otherwise deteriorating and may further be generally impervious to a broad range of corrosive elements. The non-conductive composite rail member 414 may be transparent to radio waves, microwaves, and other electromagnetic frequencies, which may result in it generally being free from interfering with electronic and wireless products, e.g., telephones, wireless routers and the like. Still further, the rail member 414 may have a low thermal conductivity, e.g., the coefficient of thermal expansion of the non-conductive composite rail member 414 may slightly less than steel and significantly less than aluminum. This may be of particular benefit when the rail member 414 supports any kind of solar capture device.

In accordance with one aspect of the present teachings, the rail member 414 may be formed of a non-conductive material to circumvent the need for any additional insulation layer, which may be required with some of the prior art version. In some embodiments, the rail member 414 may be formed from a glass fiber reinforced pultrusion. The rail member 414 being made from glass fiber reinforced pultrusion may result in it exhibiting excellent mechanical properties at extreme temperatures, whereby other such product are not capable of operating appropriately. The glass fiber reinforced non-conductive composite rail member 414 may be able to exhibit positive mechanical properties even at negative 70° F. and 200° F. In fact, the tensile strength and impact strength of glass fiber reinforced rail member 414 may be greater at negative 70° F. than at 80° F. By way of a non-limiting example, the rail member 414 may be made from a glass reinforced pultrusion such as a polyurethane, such as Baydur PUL 2500.

The rail member 414 may be generally held on a structure in any appropriate manner. In some embodiments, the rail member 414 may at least one flange 417. As depicted in FIG. 9, the rail member 414 may include a pair of flanges 417 that may extend laterally from the rail member 414. The flanges 417 may be of any appropriate shape and size. The flanges 417 may be integrally formed with the rail member 414 during pultrusion or may attached in a subsequent operation. The flanges 417 may provide balance to the rail member 414 when it is placed upon a structure. The flanges 417 may include a plurality of apertures 418 that may be spaced apart from one another positioned along a length of the flanges 417. In some embodiments, both flanges 417 may include a plurality of apertures 418 while in other embodiments, only a single flange 417 may include a plurality of apertures 418. Fasteners (not shown) may be used to secure the rail member 414 to the structure, i.e., fasteners may be inserted into and through the apertures 418. The fasteners may be secured directly to the structure or may be secured to another element secured to the structure. Any appropriate fasteners may be used without departing from the present teachings. In other embodiments, the rail member 414 may be capable of being placed on the structure and may not include fasteners—the weight of the entire support 400 with solar capture device may provide sufficient downward force to generally keep the support 400 appropriately positioned. In yet other embodiments, the rail member 414 may be adhered to the support in any appropriate manner. By way of a non-limiting example, adhesives may be used to secure the rail member 414 to the structure. Still further in other embodiments, any combination of the foregoing may be used, e.g., fasteners and adhesives.

The rail member 414 may include a slot 424 that may extend at least a portion of a length of the rail member 414. In some embodiments, the slot 424 may extend an entire length of the rail member 414. The slot 424 may be of any appropriate shape and size, as described in more detail below. The slot 424 may be formed as a monolithic unit with the rail member 414 or in the alternative may be formed through a subsequent operation. The rail member 414 may include a channel 427. In some embodiments, the channel 427 may be adjacent the slot 424, e.g., as shown in FIG. 9, the channel 427 may be positioned below the slot 424. The channel 427 may be shaped and sized so that it may be capable of holding and generally encasing any wiring that may be necessary to be operatively run between the solar capture device and the electrical system to which it may be attached.

The support 400 may include at least one bracket 431 that may secure the solar capture device to the rail member 414. The bracket 431 may include a longitudinally extending body 433. The longitudinally extending body 433 may be capable of selectively engaging the slot 424 of the rail member 414, an example of which is shown in FIG. 9. The longitudinally extending body 433 may be of a shape and size such that it may be capable of slidingly engaging the slot 424 of the rail member 414. The longitudinally extending body 433 may be made of any appropriate material. By way of a non-limiting example, the longitudinally extending body 433 may be formed through any appropriate method, including without limitation an opening molding process, such as hand lay-up, spray-up, filament winding, or any closed molding, such as compression molding, pultrusion, reinforced reaction injection molding, resin transfer molding, vacuum bag molding, vacuum infusion processing, centrifugal casting, continuous lamination or the like. In such embodiments, the longitudinally extending body 433 may be made of generally the same material as the rail 414. In the alternative, the longitudinally extending body 433 may be made of a different material.

The brackets 431 may include a solar capture device engaging member 437 that may extend from the longitudinally extending body 433 and may be attached thereto such as through the use of a fastener 438. The engaging member 437 may include a dampening member 439 that may be made of an elastomeric material. The dampening member 439 may be capable of supporting the applicable solar capture device and may act as a shock absorber such as during windy conditions. This may assist with protecting the solar capture device from certain environmental conditions.

The engaging member 437 may also include a solar capture device securing member 442 that may extend vertically upward from the dampening member 439. The securing member 442 may be capable of holding in an appropriate position the solar capture device. In some embodiments, the securing member 442 may include an elastomeric portion 447 on which the solar capture device may sit. The combination of the weight of the solar capture device and the friction occurring between contact of the solar capture device and the elastomeric portion 447 of the securing member 442 may generally prevent the solar capture device from becoming disengaged. In some embodiments, the solar capture device may be attached directly to the securing member 442 such as through the use of an appropriate fastener. In such embodiments, the fastener may be secured to the solar capture device and into the securing member 442 in any appropriate manner. Still further, the elastomeric portion 447 may prevent the solar capture device from being damaged during installation and during use thereof.

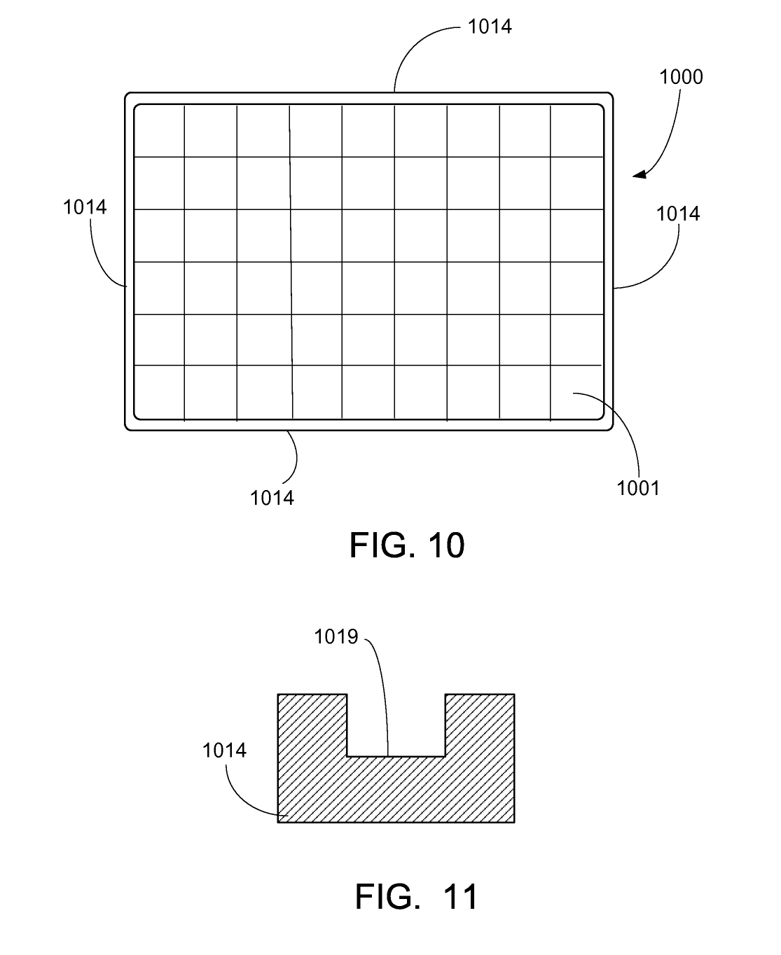

In embodiments shown in FIGS. 10-11, a support 1000 for a solar capture device 1001 may be attached to a structure, such as a building or the like. The support 1000 may be capable of securely holding the solar capture device 1001 in any appropriate manner. In these embodiments, the support 1000 may include a rail member 1014 that may attach directly to the structure in any appropriate manner. The rail member 1014 may be of any appropriate shape and size and may be of any appropriate material, such as a non-conductive composite material. The rail member 1014 may be formed through any appropriate method, including, without limitation through an opening molding process, such as hand lay-up, spray-up, filament winding, or any closed molding, such as compression molding, pultrusion, reinforced reaction injection molding, resin transfer molding, vacuum bag molding, vacuum infusion processing, centrifugal casting, continuous lamination or the like. The rail member 1014 may be generally free from any conductive material, i.e., it is made of non-electrically conductive material such that it may not be capable of transferring electricity. Instead, the rail member 1014 may act like an insulator. Further still, the rail member 1014 may be generally non-metallic, i.e., it may be generally free of metals such as aluminum any other such metals.

In one aspect of the present teachings, the rail member 1014 may be pultruded, i.e., put through a continuous process of manufacturing composite materials with generally constant cross-sectional shape whereby reinforced fibers may be pulled through a resin and into a heated die. While in the heated die, the resin may undergo polymerization, which may harden the rail member 1014 to the appropriate stiffness. The non-conductive composite rail members 1014 may be 20-25% of the weight of steel and 70% of the weight of aluminum rail members and further may be free of any conductive material. The non-conductive composite rail member 1014 may be easily transported, handled and lifted into place.

Still further, the rail member 1014 being made from non-conductive composite material may generally prevent if from rotting or otherwise deteriorating and may further be generally impervious to a broad range of corrosive elements. The non-conductive composite rail member 1014 may be transparent to radio waves, microwaves, and other electromagnetic frequencies, which may result in it generally being free from interfering with electronic and wireless products, e.g., telephones, wireless routers and the like. Still further, the coefficient of thermal expansion of the non-conductive composite rail member 1014 may be low, i.e., it may be slightly less than steel and significantly less than aluminum. This may be of particular benefit when the rail member 1014 supports any kind of solar capture device.

In accordance with one aspect of the present teachings, the rail member 1014 may be formed from a glass fiber reinforced pultrusion. The rail member 1014 being made from glass fiber reinforced pultrusion may result in it exhibiting excellent mechanical properties at extreme temperatures, whereby other such product are not capable of operating appropriately. The glass fiber reinforced non-conductive composite rail member 1014 may be able to exhibit positive mechanical properties even at negative 70° F. and 200° F. By way of a non-limiting example, the rail member 1014 may be made from a glass reinforced pultrusion such as a polyurethane, such as Baydur PUL 2500.

The rail member 1014 may generally circumscribe at least a portion of the solar capture device 1001, i.e., the rail member 1014 may frame the solar capture device 1001. By way of a non-limiting example, the solar capture device 1001 may be of a generally rectangular shape. Upon inspection of FIG. 16, the rail member 1014 may generally circumscribe the solar capture device 1001 on all four sides. The rail member 1014 may be secured to edges of the solar capture device 1001 in any appropriate manner. The solar capture device 1001 may be capable of wedgingly engaging or otherwise engaging the rail members 1014 such that the rail members 1014 may be permanently attached or may be selectively attached thereto. The present teachings are not limited to the specific manner in which the rail members 1014 attach to the solar capture device 1001—the present teachings include any appropriate manner.

In some embodiments, the rail members 1014 may include a slot 1019 of a predetermined shape and size. The slot 1019 may be of a shape and size such that the solar capture device 1001 may be capable of wedgingly or otherwise engagingly fit within the slot 109 to generally secure the solar capture device 1001 to the rail member 1014. By way of a non-limiting example, the slot 1019 may generally run an entire length of the rail member 1014. In such embodiments, the solar capture device 1001 may be inserted into the slot of the rail member 1014. These embodiments may include four rail members 1014 such that the rail members 1014 may attach to each side of the solar capture device 1001 as set forth above. The rail members 1014 may be attached to one another in any appropriate manner. Still further, the rail member 1014 may be formed such that three sides thereof are integrally formed as a monolithic member—such as through pultrusion—and then a fourth side rail member 1014 may be attached thereto with the solar capture device 1001 positioned therebetween. In yet other embodiments, the rail member 1014 may be formed such that two sides thereof are integrally formed as a monolithic member—such as through pultrusion—and then either a similarly formed two-sided rail member 1014 may be formed or two separate rail members 1014 may be formed and attached thereto with the solar capture device 1001 positioned therebetween.

While the solar capture device 1001 is shown and described as generally rectangular, the present teachings are not limited to such. The solar capture device 1001 may be of any appropriate shape, e.g., square, ovoid, oval, rhombus, parallelogram, or any combination of such shapes. The rail member 1014 may be capable of framing the solar capture device 1001 regardless of the shape of the solar capture device 1001. The rail member 1014 being formed of non-conductive composite material may allow it to generally match the shape of the solar capture device 1001 such that it may be capable of framing the solar capture device 1001 as described above regardless of the shape of the solar capture device 1001.

While certain shapes and dimensions are disclosed herein, there is no intent to limit the present teachings to the particular dimensions and shapes disclosed. The present teachings may apply to any shapes and sizes of solar capture devices. Still further, while certain solar capture devices are shown and described, there is no intent to limit the present teachings to such particular solar capture devices. The present teachings may apply to any solar capture devices, including those that may be developed hereafter.

Although the embodiments of the present teachings have been illustrated in the accompanying drawings and described in the foregoing detailed description, it is to be understood that the present invention is not to be limited to just the embodiments disclosed, but that the invention described herein is capable of numerous rearrangements, modifications and substitutions without departing from the scope of the claims hereafter. The claims as follows are intended to include all modifications and alterations insofar as they come within the scope of the claims or the equivalents thereof.

1. A support for a solar energy capture device, the support comprising:
at least one base positionable on a structure;
at least one rail secured with the base, the rail capable of operatively holding a solar energy capture device; and
at least one weight member held within with the base, the weight member capable of holding the base on the structure free from fastening the base to the structure.

2. The support of claim 1, wherein the at least one rail is formed from a non-conductive composite material.

3. The support of claim 1, wherein the at least one rail includes first and second rails formed from non-conductive composite material, wherein the first and second rails are secured with said base.

4. The support of claim 3, further comprising a plurality of bases positionable on the structure, the first and second rails being secured with the plurality of bases.

5. The support of claim 1, wherein the at least one rail is free of metal.

6. The support of claim 5, wherein the at least one rail is formed from pultrusion.

7. The support of claim 6, wherein the at least one pultruded rail includes polyurethane and glass fibers.

8. The support of claim 7, wherein the at least one rail is non-corrosive.

9. The support of claim 1, wherein the at least one weight member includes a plurality of ballasts selectively positioned on the base generally holding the base in a selected position free of fasteners.

10. The support of claim 1, wherein wires are capable of being held within the at least one rail.

11. The support of claim 1, further comprising a bracket attached to the at least one rail, wherein the bracket is capable of holding the solar capture device in an operative position.

12. A support for a solar energy capture device, the support comprising:
a rail capable of attaching to a structure, wherein the rail is formed from non-conductive composite material; and
a solar capture device holding member secured to the rail, the solar capture device holding member capable of operatively positioning the solar capture device.

13. The support of claim 12, wherein the rail is formed from polyurethane and a plurality of glass fibers.

14. The support of claim 12, wherein the rail is formed by a process from the group consisting of: hand lay-up, spray-up, filament winding, compression molding, pultrusion, reinforced reaction injection molding, resin transfer molding, vacuum bag molding, vacuum infusion processing, centrifugal casting, and continuous lamination.

15. The support of claim 12, wherein the solar capture device holding member includes a cup selectively secured to the rail, wherein the cup is capable of securing the solar capture device in an operative position.

16. The support of claim 15 wherein the rail includes at least one channel, the channel capable of holding a conductive strip in an operative position relative to the solar capture device.

17. The support of claim 12, wherein the solar capture device holding member a bracket selectively secured to the rail, wherein the bracket is capable of securing the solar capture device in an operative position.

18. The support of claim 17, wherein the rail includes a slot, the bracket capable of selectively engaging the slot.

19. The support of claim 18, wherein the pultruded rail includes at least one channel, the channel capable of holding wiring for the solar capture device.

20. The support of claim 12, wherein the rail is free of metal.

21. The support of claim 20, wherein the rail is non-corrosive.

22. A support for a solar energy capture device, the support comprising:
a non-conductive composite rail capable of attaching to a structure, wherein the rail comprises polyurethane and a plurality of glass fibers;
a conductive strip attached to the non-conductive composite rail; and
a solar capture device holding member in operative communication with the conductive strip, the solar device holding member capable of operatively positioning the solar capture device.

23. The support of claim 22, wherein the non-conductive composite rail includes at least one aperture, the solar capture device holding member positioned within the at least one aperture.

24. The support structure of claim 23, further comprising at least one solar tube attached with the solar capture device holding member.

25. The support structure of claim 22, wherein the solar capture device holding member includes a cup made of an insulative material.

26. A solar capture device comprising:
a panel member capable of capturing solar energy; and
a rail secured with the panel member, the rail being formed from non-conductive composite material.

27. The solar capture device of claim 26, wherein the rail generally circumscribes the panel member.

28. The solar capture device of claim 27, wherein the rail comprises polyurethane and a plurality of glass fibers.

29. The solar capture device of claim 28, wherein the rail is formed through pultrusion.
